(19) United States
(12) Patent Application Publication
(10) Pub. No.: US 2014/0145322 A1
(43) Pub. Date: May 29, 2014

(54) ELECTRONIC COMPONENT PACKAGE AND METHOD OF MANUFACTURING THE SAME

(71) Applicant: SAMSUNG ELECTRO-MECHANICS CO., LTD., Suwon (KR)

(72) Inventors: Young Nam HWANG, Suwon (KR); Suk Jin HAM, Seoul (KR); Seung Wan WOO, Suwon (KR); Po Chul KIM, Anyang (KR); Kyung Ho LEE, Ansan (KR)

(73) Assignee: SAMSUNG ELECTRO-MECHANICS CO., LTD., Suwon (KR)

(21) Appl. No.: 14/069,906

(22) Filed: Nov. 1, 2013

(30) Foreign Application Priority Data
Nov. 28, 2012 (KR) 10-2012-0136403

(51) Int. Cl. H01L 23/08; H01L 21/56

(52) U.S. Cl. CPC H01L 23/08; H01L 21/565
USPC 257/686; 438/124

(57) ABSTRACT

Disclosed herein are an electronic component package and a method of manufacturing the same. The electronic component package includes: a substrate; a connection member provided on at least one surface of the substrate; an active element coupled to the substrate by the connection member; and a molding part covering an exposed surface of the active element, wherein the molding part is formed of a first material having a coefficient of thermal expansion of 8 to 15 ppm/° C. and thermal conductivity of 1 to 5 W/m° C. Therefore, warpage may be significantly decreased and heat radiation performance of the active element may be improved, as compared with the case of implementing the molding part using an EMC according to the related art.

### CROSS REFERENCE(S) TO RELATED APPLICATIONS

This application claims the benefit under 35 U.S.C. Section 119, of Korean Patent Application Serial No. 10-2012-0136403, entitled “Electronic Component Package and Method of Manufacturing the Same” filed on Nov. 28, 2012, which is hereby incorporated by reference in its entirety into this application.

### BACKGROUND OF THE INVENTION

1. Technical Field

The present invention relates to an electronic component package and a method of manufacturing the same.

2. Description of the Related Art

Development of a technology for improving portability of various electronic products has been continuously conducted. As a result, technologies of mounting an electronic component on a substrate to package the electronic component have been applied.

In the package technology as described above, a molding part is generally used in order to protect the electronic component and improve convenience in manufacturing and transporting.

As an example, in Patent Documents 1, 2, or the like, a technology related to a package on package (POP) has been introduced. Particularly, in Patent Document 1, the case of implementing a molding part using an epoxy molding compound (EMC) has been introduced.

Meanwhile, in accordance with the trend toward slimness of various electronic devices, thicknesses of a substrate, a molding part, and the like, have continuously decreased. However, in the case of implementing the molding part using the EMC as in Patent Document 1, as an electronic component package is slimmed, a warpage phenomenon in a high temperature environment is intensified to decrease reliability.

In addition, circuit integration of active elements such as a mobile application processor (AP), and the like, has been significantly improved, and performance thereof has also been rapidly improved. As the performance of the active element has been improved as described above, an efficient heat radiation measure has been demanded.

However, general molding parts according to the related art such as the EMC, or the like, do not efficiently radiate heat generated in the active element. Therefore, a temperature of the active element is out of a normal operation range, such that the active element is not normally operated or is determined.

### RELATED ART DOCUMENT

### Patent Document

(Patent Document 1) Korean Patent Laid-Open Publication No. 2012-0007840

(Patent Document 2) Korean Patent Laid-Open Publication No. 2011-0076604

### SUMMARY OF THE INVENTION

An object of the present invention is to provide an electronic component package capable of decreasing a warpage phenomenon and improving heat radiation performance.

Another object of the present invention is to provide a manufacturing method of manufacturing an electronic component package capable of decreasing a warpage phenomenon and improving heat radiation performance.

According to an exemplary embodiment of the present invention, there is provided an electronic component package including: a substrate; a connection member provided on at least one surface of the substrate; an active element coupled to the substrate by the connection member; and a molding part covering an exposed surface of the active element, wherein the molding part is formed of a first material having a coefficient of thermal expansion of 8 to 15 ppm/° C. and thermal conductivity of 1 to 5 W/m° C.

The first material may be at least one material selected from a group consisting of liquid crystal polymer, polyamide, and polyphenylene sulfide.

The electronic component package may be any one of an upper layer package and a lower layer package configuring a package-on-package.

The connection member may be made of at least one material selected from a group consisting of a synthetic resin and a solder paste.

According to another exemplary embodiment of the present invention, there is provided an electronic component package including: a first substrate; a first connection member provided on an upper surface of the first substrate; a first active element coupled to the first substrate by the first connection member; a first molding part covering an exposed surface of the first active element; a first connection pad provided on a lower surface of the first substrate; a second substrate having an upper surface contacted by the first connection pad; a second connection member provided on the upper surface of the second substrate; a second active element coupled to the second substrate by the second connection member; and a second molding part filled between the upper surface of the second substrate and the lower surface of the first substrate, wherein at least one of the first and second molding parts is formed of a first material having a coefficient of thermal expansion of 8 to 15 ppm/° C. and thermal conductivity of 1 to 5 W/m° C.

The first material may be at least one material selected from a group consisting of liquid crystal polymer, polyamide, and polyphenylene sulfide.

The electronic component package may further include a second connection pad provided on a lower surface of the second substrate.

At least one of the first and second connection members may be made of at least one material selected from a group consisting of a synthetic resin and a solder paste.

According to still another exemplary embodiment of the present invention, there is provided a method of manufacturing an electronic component package, the method including: providing a connection member on at least one surface of a substrate; coupling an active element to a surface of the connection member; and forming a molding part covering an exposed surface of the active element using a first material having a coefficient of thermal expansion of 8 to 15 ppm/° C. and thermal conductivity of 1 to 5 W/m° C.

The first material may be at least one material selected from a group consisting of liquid crystal polymer, polyamide, and polyphenylene sulfide.

In the providing of the connection member on the at least one surface of the substrate, the connection member may be made of at least one material selected from a group consisting of a synthetic resin and a solder paste.

### BRIEF DESCRIPTION OF THE DRAWINGS

FIG. 1 is a cross-sectional view schematically showing an electronic component package according to an exemplary embodiment of the present invention;

FIG. 2 is a cross-sectional view schematically showing an electronic component package according to another exemplary embodiment of the present invention;

FIG. 3 is a view schematically showing a simulation result for warpage of the electronic component package shown in FIG. 1 in the state in which a first molding part is implemented using a material having a coefficient of thermal expansion of 8 ppm/° C.;

FIG. 4 is a view schematically showing a simulation result for warpage of the electronic component package shown in FIG. 1 in the state in which a first molding part is implemented using a material having a coefficient of thermal expansion of 11 ppm/° C.;

FIG. 5 is a view schematically showing a simulation result for warpage of the electronic component package shown in FIG. 1 in the state in which a first molding part is implemented using a material having a coefficient of thermal expansion of 14.5 ppm/° C.;

FIG. 6 is a view schematically showing a simulation result for warpage of the electronic component package shown in FIG. 1 in the state in which a first molding part is implemented using a material having a coefficient of thermal expansion of 15 ppm/° C.;

FIG. 7 is a graph schematically showing a change in warpage according to coefficients of thermal expansion;

FIG. 8 is a view schematically showing a simulation result for a temperature of an active element of the electronic component package shown in FIG. 1 in the state in which a first molding part is implemented using a material having a coefficient of thermal conduction of 1 W/m° C.;

FIG. 9 is a view schematically showing a simulation result for a temperature of the active element of the electronic component package shown in FIG. 1 in the state in which a first molding part is implemented using a material having a coefficient of thermal conduction of 5 W/m° C.;

FIG. 10 is a view schematically showing a simulation result for a temperature of the active element of the electronic component package shown in FIG. 1 in the state in which a first molding part is implemented using a material having a coefficient of thermal conduction of 0.5 W/m° C.;

FIG. 11 is a graph schematically showing a change in a temperature of the active element according to coefficients of thermal conduction; and

FIG. 12 is a view schematically showing a method of manufacturing an electronic component package according to the exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Like reference numerals throughout the description denote like elements.

Terms used in the present specification are for explaining exemplary embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth” and the like, if any, will be used to distinguish similar components from each other and be used to describe a specific sequence or a generation sequence, but is not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

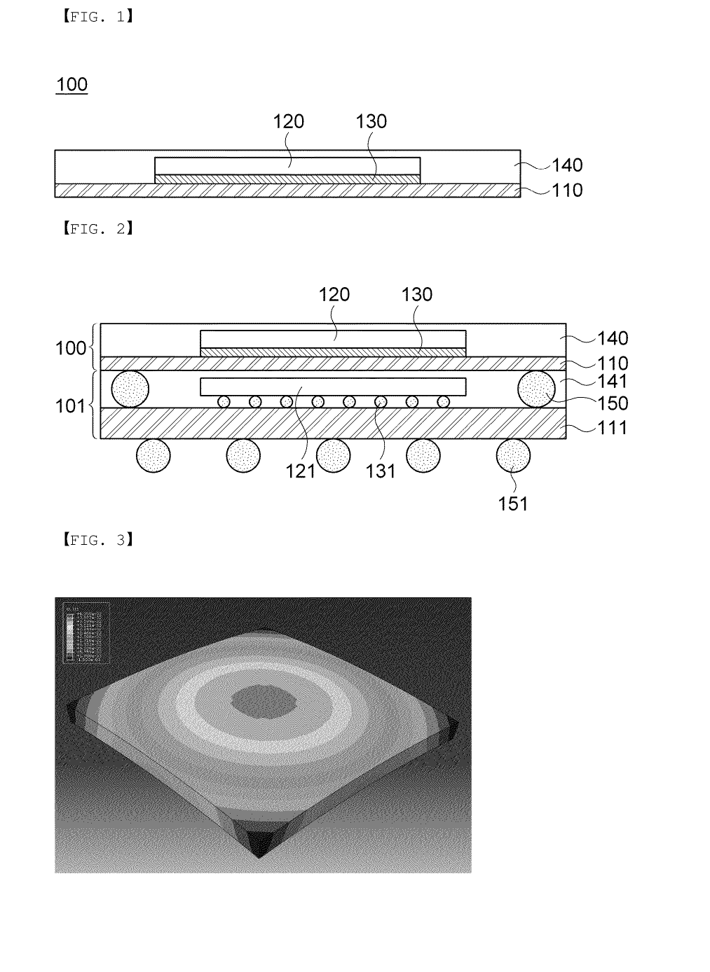

FIG. 1 is a cross-sectional view schematically showing an electronic component package 100 according to an exemplary embodiment of the present invention.

Referring to FIG. 1, the electronic component package 100 according to the exemplary embodiment of the present invention may be configured to include a first substrate 110, a first connection member 130, a first active element 120, and a first molding part 140.

The first substrate 110 may be a general printed circuit board (PCB), or the like.

The first active element 120 may be various active elements such as an integrated circuit (IC), or the like.

The first connection member 130 may be implemented using a synthetic resin such as epoxy, or the like, or various conductive solders.

The first connection member 130 is provided on an upper surface of the first substrate 110 to serve to electrically and physically connect between the first active element 120 and the first substrate 110.

The first molding part 140 covers an exposed surface of the first active element 120 to serve to protect the first active element 120.

Particularly, it is preferable that the first molding part 140 is made of a first material of a coefficient of thermal expansion of 8 to 15 ppm/° C. and thermal conductivity of 1 to 5 W/m° C.

In addition, it is preferable that the first molding part 140 is implemented using at least one material selected from a group consisting of liquid crystal polymer, polyamide, and polyphenylene sulfide.

Further, the first molding part 140 may also cover the first substrate 110 in the vicinity of the first active element 120.

FIG. 2 is a cross-sectional view schematically showing an electronic component package 100 according to another exemplary embodiment of the present invention.

Unlike the electronic component package 100 according to the exemplary embodiment described above with reference to FIG. 1, the electronic component package 100 according to the present embodiment may have a POP structure in which a package is formed in two layers.

Hereinafter, portions different from those of the electronic component package 100 according to the exemplary embodiment described above will be mainly described.

The electronic component package 100 according to another exemplary embodiment of the present invention may be configured to include a first substrate 110, a first connection member 130, a first active element 120, a first molding part 140, a first connection pad 150, a second substrate 111, second connection members 131, a second active element 121, a second molding part 141, and a second connection pad 151.

Here, it is preferable that at least one of the first molding part 140 and the second molding part 141 is made of a first material of a coefficient of thermal expansion of 8 to 15 ppm/° C. and thermal conductivity of 1 to 5 W/m° C. and 140 is implemented using at least one material selected from a group consisting of liquid crystal polymer, polyamide, and polyphenylene sulfide.

The first connection pad 150 may be formed on a lower surface of the first substrate 110 to contact a circuit pattern formed on an upper surface of the second substrate 111. Therefore, the first active element 120 and the first substrate 110 may be electrically connected to the second substrate 111 by the first connection pad 150.

The second molding part 141 may fill an empty space between the lower surface of the first substrate 110 and the upper surface of the second substrate 111. Therefore, the second molding part 141 may protect the surface of the second substrate 111 as well as the second active element 121 and improve adhesive force between the first and second substrates 110 and 111.

The second connection pad 151 may be connected to a lower portion of the second substrate 111 to electrically connect the electronic component package 100 to other devices.

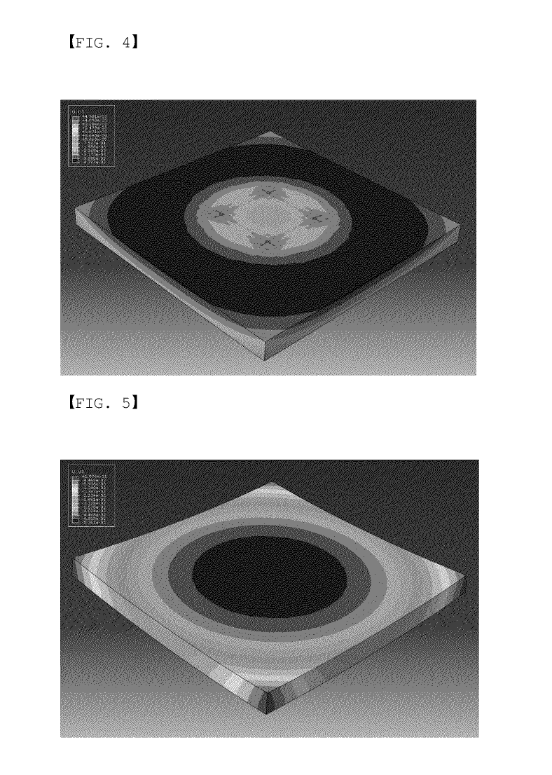

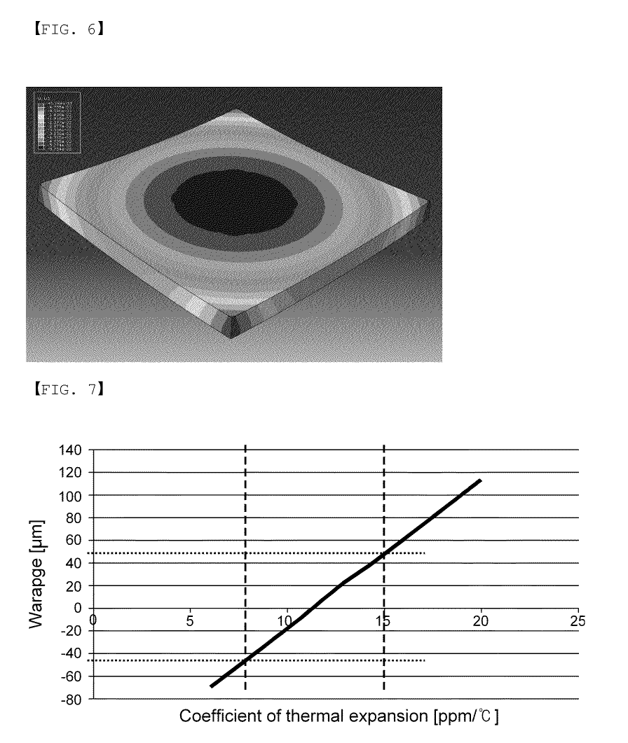

FIG. 3 is a view schematically showing a simulation result for warpage of the electronic component package 100 shown in FIG. 1 in the state in which a first molding part 140 is implemented using a material having a coefficient of thermal expansion of 8 ppm/° C.; FIG. 4 is a view schematically showing a simulation result for warpage of the electronic component package 100 shown in FIG. 1 in the state in which a first molding part 140 is implemented using a material having a coefficient of thermal expansion of 11 ppm/° C.; FIG. 5 is a view schematically showing a simulation result for warpage of the electronic component package 100 shown in FIG. 1 in the state in which a first molding part 140 is implemented using a material having a coefficient of thermal expansion of 14.5 ppm/° C.; and FIG. 6 is a view schematically showing a simulation result for warpage of the electronic component package 100 shown in FIG. 1 in the state in which a first molding part 140 is implemented using a material having a coefficient of thermal expansion of 15 ppm/° C.

Referring to FIGS. 3 to 6, a relationship between a coefficient of thermal expansion and warpage as shown in the following Table 1 may be confirmed.

TABLE 1

| Coefficient of thermal | |
|---|---|
| expansion (ppm/° C.) | Warpage (μm) |
| 8 | −43.5 |
| 11 | −7.4 |
| 14.5 | 47.2 |
| 15 | 51.2 |

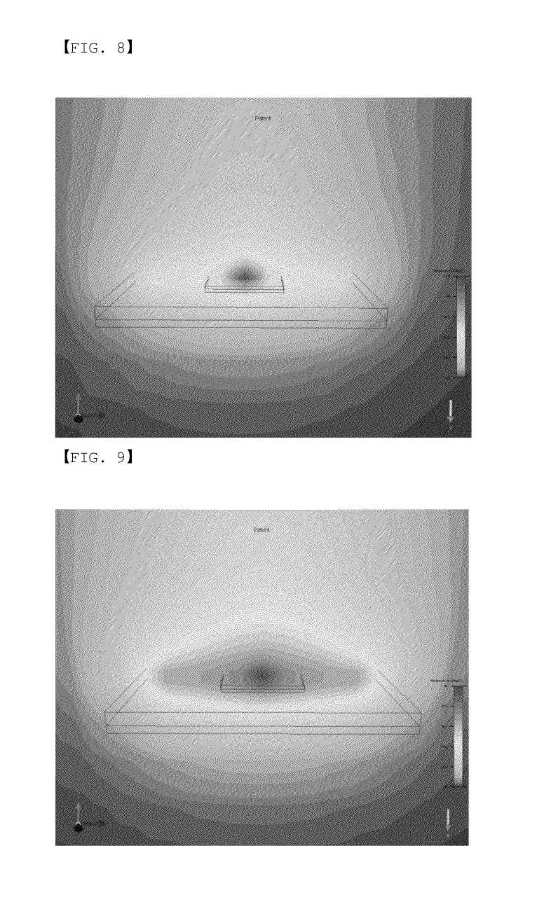

FIG. 7 is a graph schematically showing a change in warpage according to coefficients of thermal expansion.

Referring to FIG. 7, as a result obtained by measuring warpage of the substrate while changing a thermal of the first material forming the first molding part 140, it could be confirmed that there is a linear relationship between a change in the coefficient of thermal expansion and the warpage.

Meanwhile, an epoxy molding compound (EMC) widely used as a molding material according to the related art has a coefficient of thermal expansion of 16 to 20 ppm/° C. Therefore, in the case of implementing the first molding part 140 using the EMC, warpage exceeds 52 μm to cause a serious defect in the electronic component package 100.

In addition, this phenomenon is further intensified as the electronic component package 100 becomes thin.

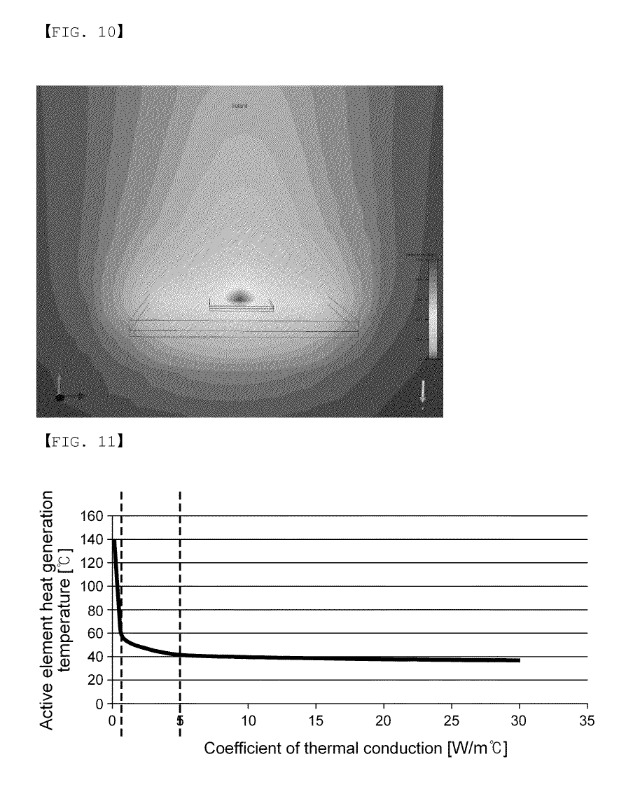

FIG. 8 is a view schematically showing a simulation result for a temperature of an active element of the electronic component package 140 shown in FIG. 1 in the state in which a first molding part 140 is implemented using a material having a coefficient of thermal conduction of 1 W/m° C.; FIG. 9 is a view schematically showing a simulation result for a temperature of the active element of the electronic component package 100 shown in FIG. 1 in the state in which a first molding part 140 is implemented using a material having a coefficient of thermal conduction of 5 W/m° C.; and FIG. 10 is a view schematically showing a simulation result for a temperature of the active element of the electronic component package 100 shown in FIG. 1 in the state in which a first molding part 140 is implemented using a material having a coefficient of thermal conduction of 0.5 W/m° C.

Referring to FIGS. 8 to 10, a relationship between a coefficient of thermal conduction and warpage as shown in the following Table 2 may be confirmed.

TABLE 2

| Coefficient of thermal | Active element heat generation |
|---|---|
| conduction (W/m ° C.) | temperature (° C.) |
| 1 | 53.8 |
| 5 | 42.0 |
| 0.5 | 64.4 |

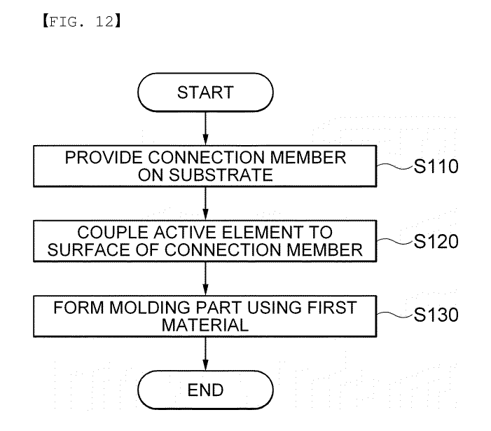

FIG. 11 is a graph showing a change in a temperature of the active element according to coefficients of thermal conduction.

Referring to FIG. 11, as a result obtained by measuring a temperature of the active element while changing a coefficient of thermal conduction of the first material forming the first molding part 140, it could be confirmed that in a section in which the coefficient of thermal conduction is smaller than 1 W/m° C., the smaller the coefficient of thermal conduction, the more rapidly the temperature of the active element increases, and in a section in which the coefficient of thermal conduction exceeds 5 W/m° C., a change in the coefficient of thermal conduction does not substantially have an effect on the temperature of the active element.

Meanwhile, an epoxy molding compound (EMC) widely used as a molding material according to the related art has a coefficient of thermal conduction of 0.5 to 0.8 W/m° C. Therefore, in the case of implementing the first molding part 140 using the EMC, a temperature of the active element exceeds 64° C., such that a normal operation of the active element may become difficult.

In the electronic component package 100 according to the exemplary embodiment of the present invention, as the first material implementing the first molding part 140, a material having a coefficient of thermal expansion that is in a range of 8 to 15 ppm/° C. and thermal conductivity of 1 to 5 W/m° C., particularly, a material selected from a group consisting of liquid crystal polymer, polyamide, and polyphenylene sulfide is used.

Therefore, the warpage may be significantly decreased and the heat radiation performance of the active element may be improved, as compared with the case of implementing the first molding part 140 using the EMC according to the related art as described above.

FIG. 12 is a view schematically showing a method of manufacturing an electronic component package according to the exemplary embodiment of the present invention.

Referring to FIG. 12, first, a connection member is formed on one surface of a substrate (S110).

In this case, the connection member may be made of at least one material selected from a group consisting of a synthetic resin and a solder paste.

Then, an active element is coupled to a surface of the connection member (S120).

Next, a first material having a coefficient of thermal expansion of 8 to 15 ppm/° C. and thermal conductivity of 1 to 5 W/m° C. is used to cover an exposed surface of the active element, thereby forming a molding part (S130).

In this case, the molding part may also cover the substrate in vicinity of the active element.

Therefore, the warpage may be significantly decreased and the heat radiation performance of the active element may be improved, as compared with the case of implementing the molding part using the EMC according to the related art as described above.

The electronic component package according to the exemplary embodiment of the present invention configured as described above may minimize warpage and maximize heat radiation performance.

What is claimed is:

1. An electronic component package comprising:
a substrate;
a connection member provided on at least one surface of the substrate;
an active element coupled to the substrate by the connection member; and
a molding part covering an exposed surface of the active element,
wherein the molding part is formed of a first material having a coefficient of thermal expansion of 8 to 15 ppm/° C. and thermal conductivity of 1 to 5 W/m° C.

2. The electronic component package according to claim 1, wherein the first material is at least one material selected from a group consisting of liquid crystal polymer, polyamide, and polyphenylene sulfide.

3. The electronic component package according to claim 2, wherein it is any one of an upper layer package and a lower layer package configuring a package-on-package.

4. The electronic component package according to claim 2, wherein the connection member is made of at least one material selected from a group consisting of a synthetic resin and a solder paste.

5. An electronic component package comprising:
a first substrate;
a first connection member provided on an upper surface of the first substrate;
a first active element coupled to the first substrate by the first connection member;
a first molding part covering an exposed surface of the first active element;
a first connection pad provided on a lower surface of the first substrate;
a second substrate having an upper surface contacted by the first connection pad;
a second connection member provided on the upper surface of the second substrate;
a second active element coupled to the second substrate by the second connection member; and
a second molding part filled between the upper surface of the second substrate and the lower surface of the first substrate,
wherein at least one of the first and second molding parts is formed of a first material having a coefficient of thermal expansion of 8 to 15 ppm/° C. and thermal conductivity of 1 to 5 W/m° C.

6. The electronic component package according to claim 5, wherein the first material is at least one material selected from a group consisting of liquid crystal polymer, polyamide, and polyphenylene sulfide.

7. The electronic component package according to claim 6, further comprising a second connection pad provided on a lower surface of the second substrate.

8. The electronic component package according to claim 6, wherein at least one of the first and second connection members is made of at least one material selected from a group consisting of a synthetic resin and a solder paste.

9. A method of manufacturing an electronic component package, the method comprising:
providing a connection member on at least one surface of a substrate;
coupling an active element to a surface of the connection member; and
forming a molding part covering an exposed surface of the active element using a first material having a coefficient of thermal expansion of 8 to 15 ppm/° C. and thermal conductivity of 1 to 5 W/m° C.

10. The method according to claim 9, wherein the first material is at least one material selected from a group consisting of liquid crystal polymer, polyamide, and polyphenylene sulfide.

11. The method according to claim 10, wherein in the providing of the connection member on the at least one surface of the substrate, the connection member is made of at least one material selected from a group consisting of a synthetic resin and a solder paste.
